(19) United States
(12) Patent Application Publication
(10) Pub. No.: US 2006/0205166 A1
(43) Pub. Date: Sep. 14, 2006

(54) SEMICONDUCTOR DEVICE AND METHOD FOR MANUFACTURING THE SAME

(75) Inventor: Mamoru ISHIKIRIYAMA, Miyazaki (JP)

Correspondence Address: STEVEN ROBERTS;SHINJYU GLOBAL IP, SOUTH FOREST BLDG., 11TH FLOOR, 1-4-19, MINAMIMORI-MACHI, KITA-KU, OSAKA, 530-0054, JP

(73) Assignee: OKI ELECTRIC INDUSTRY CO., LTD., Tokyo (JP)

(21) Appl. No.: 11/276,405

(22) Filed: Feb. 28, 2006

(30) Foreign Application Priority Data
Mar. 10, 2005 (JP) 2005/067575

(51) Int. Cl. H01L 21/336

(52) U.S. Cl. 438/299; 438/306

(57) ABSTRACT

A method for manufacturing a semiconductor device includes the steps of (a) forming a gate insulating film above a semiconductor substrate, (b) forming a first conductive film on the gate insulating film, (c) forming a first insulating film pattern on the first conductive film, (d) selectively forming a first impurity diffusion layer in the semiconductor substrate by ion implantation, (e) selectively forming a first selective insulating film that overlaps with the first impurity diffusion layer in a self-alignment fashion in the first conductive film, (f) forming a gate electrode that has a gate edge self-aligned with the first impurity diffusion layer and overlaps with the first impurity diffusion layer in a self-alignment fashion, and (g) selectively forming a second impurity diffusion layer that is located adjacent to the first impurity diffusion layer and is self-aligned with the gate edge by ion implantation.

### BACKGROUND OF THE INVENTION

Field of the Invention

The present invention relates to a method for manufacturing a semiconductor device, especially a method for manufacturing a high voltage metal oxide semiconductor (MOS) transistor having an electric field reduction layer comprised of a lightly doped diffusion layer that overlaps with a gate electrode.

In general, high voltage is applied to a drain electrode in a high voltage MOS transistor. Because of this, electric field concentration is caused in a lightly doped diffusion layer on a drain electrode side, which is formed directly below a gate electrode. Then, the electric field concentration leads to impact ionization, and thus high energy electrons and electron holes are injected into and trapped in a gate insulating film formed on the lightly doped diffusion layer. This causes device properties to be changed over time.

The offset structure has been heretofore provided, in which a heavily doped diffusion region comprising a source/drain is separated from a gate electrode in order to reduce electric field in a lower edge of the gate electrode. Japanese Patent Publication JP-A-09-205205 (especially paragraph numbers 0013-0020 and FIGS. 3 and 4) discloses an offset structure. In this offset structure, a spacer is formed adjacent to a sidewall of a gate electrode, and a lightly doped diffusion region is formed immediately below the spacer. Therefore, a heavily doped diffusion region is separated (i.e., “offset”) from the gate electrode by substantially the distance of the spacer. Here, the amount of the offset is increased in order to have a profound electric field reduction effect.

Another structure to reduce the electric field in a lower edge of a gate electrode has been heretofore known, in which a lightly doped diffusion layer functioning as an electric field reduction layer overlaps with a gate electrode. Japanese Patent Publication JP-A-2003-100771 (especially paragraph numbers 0025 and FIGS. 2 and 6) discloses a heretofore known gate overlap structure of a high voltage MOS transistor. In this overlap structure, a portion of a lightly doped diffusion layer formed in a drain region overlaps with a gate electrode. An ion implantation process is conducted by using a mask formed on a gate insulating film, and a lightly doped diffusion layer is selectively formed on a semiconductor substrate. Then, a polysilicon layer is formed on the gate insulating film, and a gate electrode, which overlaps with the lightly doped diffusion layer by the predetermined distance, is formed by patterning the polysilicon layer. Therefore, the lightly doped diffusion layer can be formed without depending on the length of the gate electrode. According to this Japanese Patent Publication, increasing the amount of the overlap is effective in order to have a profound electric field reduction effect.

The above described heretofore known methods for forming the gate overlap structure have been suggested to increase the electric field reduction effect. However, the following problems are actually caused in those methods.

First, in the above mentioned methods, it is required to form a gate electrode after a lightly doped diffusion layer is formed. Because of this, the overlap dimension between the lightly doped diffusion layer and the gate electrode is required to be defined in consideration of the alignment margin between the patterning to form the lightly doped diffusion layer and the patterning to form the gate electrode. In other words, a design value is required to be set to be the value derived by adding the alignment margin between the patterning to form the lightly doped diffusion layer and the patterning to form the gate electrode to the originally necessary overlap dimension between the lightly doped diffusion layer and the gate electrode. Because of this, current drive capability has been reduced and device miniaturization has been prevented.

Second, the following problem can be caused because of the order in which a gate electrode is formed after a lightly doped diffusion layer is formed. When the heretofore known lithography technique is used for the above mentioned methods, a lightly doped diffusion layer is asymmetrically formed with respect to a gate electrode when the alignment between the patterning to form the lightly doped diffusion layer and the patterning to form the gate electrode is incorrectly completed. Because of this, device properties have been varied.

Third, when the heretofore known lithography technique is used for the above mentioned methods, the distance between a heavily doped diffusion layer and a gate electrode is required to be defined in consideration of the alignment margin between the patterning to form the heavily doped diffusion layer and the patterning to form the gate electrode. In other words, a design value is required to be set to be the value derived by adding the alignment margin between the patterning to form the heavily doped diffusion layer and the patterning to form the gate electrode to the originally necessary distance between the heavily doped diffusion layer and the gate electrode. Because of this, current drive capability has been further reduced and device properties have been varied. Furthermore, device miniaturization has been prevented.

### SUMMARY OF THE INVENTION

It is therefore an object of the present invention to provide a high voltage MOS transistor without the above described problems.

In accordance with a first aspect of the present invention, a semiconductor device is comprised of a gate insulating film formed above a semiconductor substrate, a gate electrode formed on the gate insulating film, a first selective insulating film that is formed on the gate electrode and defines a gate edge of the gate electrode, a first impurity diffusion layer that overlaps with the selective insulating film in a self-alignment fashion and overlaps with the gate electrode in a self-alignment fashion, and a second impurity diffusion layer whose boundary with the first impurity diffusion layer is self-aligned with the gate edge.

In accordance with a second aspect of the present invention, in the semiconductor device according to the first aspect of the present invention, the gate electrode is comprised of a polysilicon film, and the selective insulating film is comprised of a thermal oxide silicon film.

In accordance with a third aspect of the present invention, in the semiconductor device according to the first aspect of the present invention, the semiconductor device is further comprised of a third impurity diffusion layer that is formed in the second impurity diffusion layer and is offset from the gate electrode in a self-alignment fashion.

In accordance with a fourth aspect of the present invention, in the semiconductor device according to the first aspect of the present invention, the first impurity diffusion layer is comprised of a first pair of impurity diffusion regions that are separated from each other to be symmetrical with respect to the gate electrode, and the second impurity diffusion layer is comprised of a second pair of impurity diffusion regions that are separated from each other to be symmetrical with respect to the gate electrode, and the first selective insulating film is comprised of a first pair of insulating layers that are separated from each other to be symmetrical with respect to the gate electrode.

In accordance with a fifth aspect of the present invention, in the semiconductor device according to the fourth aspect of the present invention, the third impurity diffusion layer is comprised of a third pair of impurity diffusion regions that are separated to be symmetrical with respect to the gate electrode.

In accordance with a sixth aspect of the present invention, in the semiconductor device according to the first aspect of the present invention, the first impurity diffusion layer is comprised of a first single impurity diffusion region, and the second impurity diffusion layer is comprised of a second single impurity diffusion region, and the first selective insulating film is comprised of a first single insulating film.

Furthermore, it is also an object of the present invention to provide a method for manufacturing a high voltage MOS transistor without the above described problems.

In accordance with the present invention, a method for forming a semiconductor device is comprised of the steps of (a) forming a gate insulating film above a semiconductor substrate, (b) forming a first conductive film on the gate insulating film, (c) forming a first insulating film pattern on the first conductive film, (d) selectively forming a first impurity diffusion layer in the semiconductor substrate by implanting impurity ions into the semiconductor substrate by using at least the first insulating pattern as a mask, (e) selectively forming a first selective insulating film that overlaps with the first impurity diffusion layer in a self-alignment fashion in the first conductive film by using the first insulating film pattern as a mask, (f) forming a gate electrode that has a gate edge, which is self-aligned with the first impurity diffusion layer and defined by the first selective insulating film by selectively etching the first conductive film by using at least the first selective insulating film as a mask, and overlaps with the first impurity diffusion layer in a self-alignment fashion, and (g) selectively forming a second impurity diffusion layer that is located adjacent to the first impurity diffusion layer and is self-aligned with the gate edge by implanting impurities into the semiconductor substrate by using the gate electrode as a mask.

According to the present invention, the first impurity diffusion layer and the selective insulating film that defines the gate electrode edge are both formed in a self-alignment fashion by using the first insulating film pattern as a mask. Furthermore, the second impurity diffusion layer adjacent to the first impurity diffusion layer is formed in a self-alignment fashion by using the gate electrode as a mask. As a result, the boundary between the first impurity diffusion layer and the second impurity diffusion layer is self-aligned with the gate electrode edge. Also, the first impurity diffusion layer functioning as an electric field reduction layer and the selective insulating film that defines the gate electrode edge are overlapped with each other in a self-alignment fashion. The first impurity diffusion layer that overlaps with the edge vicinity of the gate electrode and functions as the electric field reduction layer is formed to be self-aligned with the gate electrode edge. This self-alignment gate overlap structure has the following effects.

According to the structure, it is possible to define the overlap dimension between the first impurity diffusion layer and the gate electrode without considering the alignment margin between the patterning to form the first impurity diffusion layer and the patterning to form the gate electrode. When the gate overlap structure is formed in a non-self-alignment fashion, a design value is required to be set to be the value derived by adding the above described alignment margin between the patterning to form the first impurity diffusion layer and the patterning to form the gate electrode to the originally necessary gate overlap dimension. On the other hand, when the gate overlap structure is formed in a self-alignment fashion, the above described alignment margin between the patternings is not needed and a design value may be set to be the value of the originally necessary gate overlap dimension. Because of this, current drive capability can be improved and a device can be miniaturized.

### BRIEF DESCRIPTION OF THE DRAWINGS

Referring now to the attached drawings which form a part of this original disclosure:

FIGS. 1A to 1C are partial vertical cross-section diagrams showing a method for manufacturing a high voltage MOS transistor in accordance with the first embodiment of the present invention.

FIGS. 2A to 2C are partial vertical cross-section diagrams showing a method for manufacturing a high voltage MOS transistor in accordance with the first embodiment of the present invention.

FIGS. 3A to 3C are partial vertical cross-section diagrams showing a method for manufacturing a high voltage MOS transistor in accordance with the first embodiment of the present invention.

FIGS. 4A to 4C are partial vertical cross-section diagrams showing a method for manufacturing a high voltage MOS transistor in accordance with the first embodiment of the present invention.

FIGS. 5A to 5C are partial vertical cross-section diagrams showing a method for manufacturing a high voltage MOS transistor in accordance with the first embodiment of the present invention.

FIG. 6 is a plan view of a substrate in the manufacturing step shown in FIG. 5B.

FIGS. 7A to 7C are partial vertical cross-section diagrams showing a method for manufacturing a high voltage MOS transistor in accordance with the second embodiment of the present invention.

FIGS. 8A to 8C are partial vertical cross-section diagrams showing a method for manufacturing a high voltage MOS transistor in accordance with the second embodiment of the present invention.

FIGS. 9A to 9C are partial vertical cross-section diagrams showing a method for manufacturing a high voltage MOS transistor in accordance with the second embodiment of the present invention.

FIGS. 10A to 10C are partial vertical cross-section diagrams showing a method for manufacturing a high voltage MOS transistor in accordance with the second embodiment of the present invention.

FIGS. 11A to 11C are partial vertical cross-section diagrams showing a method for manufacturing a high voltage MOS transistor in accordance with the second embodiment of the present invention.

FIGS. 12A to 12C are partial vertical cross-section diagrams showing a method for manufacturing a high voltage MOS transistor in accordance with the third embodiment of the present invention.

FIGS. 13A to 13C are partial vertical cross-section diagrams showing a method for manufacturing a high voltage MOS transistor in accordance with the third embodiment of the present invention.

FIGS. 14A to 14C are partial vertical cross-section diagrams showing a method for manufacturing a high voltage MOS transistor in accordance with the third embodiment of the present invention.

FIGS. 15A to 15C are partial vertical cross-section diagrams showing a method for manufacturing a high voltage MOS transistor in accordance with the third embodiment of the present invention.

FIGS. 16A to 16C are partial vertical cross-section diagrams showing a method for manufacturing a high voltage MOS transistor in accordance with the third embodiment of the present invention.

FIGS. 17A to 17C are partial vertical cross-section diagrams showing a method for manufacturing a high voltage MOS transistor in accordance with the third embodiment of the present invention.

FIG. 18 is a plan view of a substrate in the manufacturing step shown in FIG. 13B.

FIG. 19 is partial vertical cross-section diagrams showing another embodiment of a high voltage MOS transistor in accordance with the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

Referring now to the drawings, preferred embodiments of the present invention will be described in detail.

### First Embodiment

According to the first embodiment of the present invention, a high voltage MOS transistor is provided, which has a lightly doped diffusion layer overlapping with an edge vicinity region of a gate electrode in a self-alignment fashion and functioning as an electric field reduction layer. Also, according to the first embodiment of the present invention, a method for manufacturing the above described high voltage MOS transistor is provided.

High Voltage MOS Transistor Structure

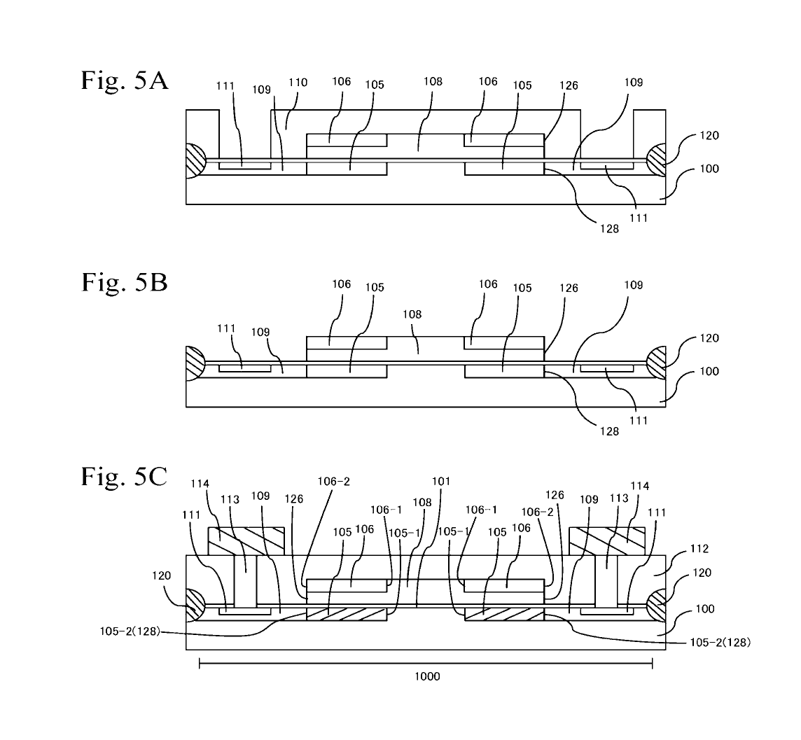

FIG. 5C is a partial vertical cross-section diagram that shows the structure of a high voltage MOS transistor in accordance with the first embodiment of the present invention.

The high voltage MOS transistor according to the first embodiment of the present invention has the following structure. The principal surface of a p-type single crystal silicon substrate 100 includes an element isolation region comprised of a field oxide film 120 and an active region 1000 defined by the field oxide film 120. A first lightly doped N⁻ diffusion layer 105 and a second lightly doped N⁻ diffusion layer 109 are formed in the active region 1000 of the p-type single crystal silicon substrate 100. The first lightly doped N⁻ diffusion layer 105 and the second lightly doped N⁻ diffusion layer 109 are adjacently formed with each other through a boundary 128. A first heavily doped N⁺ diffusion layer 111 is selectively formed in an upper region of the second lightly doped N⁻ diffusion layer 109. A first heavily doped N⁺ diffusion layer 111 is separated from the first lightly doped N⁻ diffusion layer 105 through the second lightly doped N⁻ diffusion layer 109. The first lightly doped N⁻ diffusion layers 105 are mutually separated through a channel region comprised of a selective upper region of the p-type single crystal silicon substrate 100.

A gate oxide film 101 is formed on the principal surface of the p-type single crystal silicon substrate 100. In other words, a gate oxide film 101 is continuously formed on the first lightly doped N⁻ diffusion layer 105, a second lightly doped N⁻ diffusion layer 109, and a first heavily doped N⁺ diffusion layer 111. A polysilicon gate electrode 108 is selectively formed on the gate oxide film 101. A thermal oxide film 106 is formed in the vicinity of the edge of the upper region (hereinafter called an edge vicinity) of the polysilicon gate electrode 108. The thermal oxide film 106 is self-aligned with the first lightly doped N⁻ diffusion layer 105 when seen in a horizontal position. In the present patent application, the term “the horizontal direction” means the direction that is parallel to the length direction of a channel and included in a surface parallel to the substrate surface. In other words, an inner edge 106-1 of the thermal oxide film 106 is self-aligned with an inner edge 105-1 of the first lightly doped N⁻ diffusion layer 105 when seen in a horizontal position. On the other hand, an outer edge 106-2 of the thermal oxide film 106 is self-aligned with an outer edge 105-2 of the first lightly doped N⁻ diffusion layer 105 when seen in a horizontal position. A gate electrode edge 126 of the polysilicon gate electrode 108 is self-aligned with the outer edge 106-2 of the thermal oxide film 106 when seen in a horizontal position. Also, the boundary 128 between the first lightly doped N⁻ diffusion layer 105 and the second lightly doped N⁻ diffusion layer 109 corresponds to the outer edge 105-2 of the first lightly doped N⁻ diffusion layer 105. Therefore, the gate electrode edge 126 of the polysilicon gate electrode 108 is self-aligned with the boundary 128 between the first lightly doped N⁻ diffusion layer 105 and the second lightly doped N⁻ diffusion layer 109 when seen in a horizontal position. In other words, the first lightly doped N⁻ diffusion layer 105 overlaps with the polysilicon gate electrode 108 in a self-alignment fashion and thus functions as an electric field reduction layer.

An interlayer insulating film 112 is formed on the polysilicon gate electrode 108, the thermal oxide film 106, and the gate oxide film 101. A source/drain contact 113 is formed in a contact hole formed in the interlayer insulating film 112. The source/drain contact 113 has an ohmic contact with the first heavily doped N⁺ diffusion layer 111. A source/drain wiring layer 114 is formed on the interlayer insulating film 112 and electrically connected to the first heavily doped N⁺ diffusion layer 111 through the source/drain contact 113.

The following is the main structural difference between heretofore known high voltage MOS transistors and the high voltage MOS transistor in accordance with the first embodiment of the present invention. The high voltage MOS transistor in accordance with the first embodiment of the present invention has a structure in which the first lightly doped N⁻ diffusion layer 105 overlaps with the polysilicon gate electrode 108 in a self-alignment fashion.

Method For Manufacturing High Voltage MOS Transistor

With reference to attached figures, a method for manufacturing the high voltage MOS transistor in accordance with the first embodiment of the present invention is hereinafter explained.

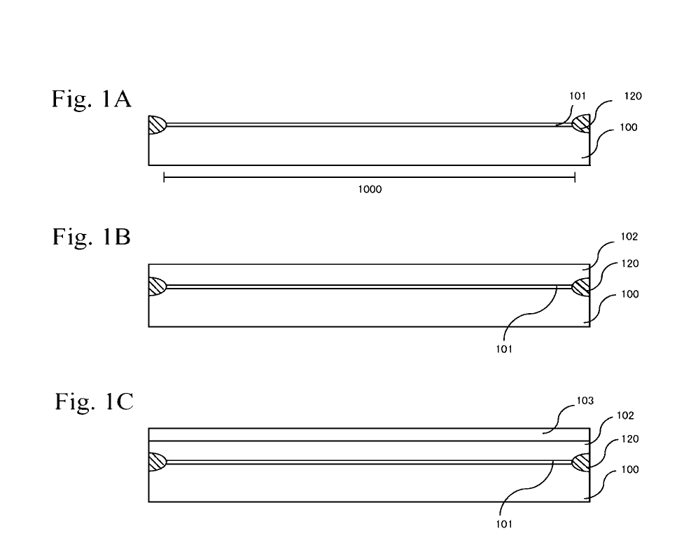

FIGS. 1A to 1C, 2A to 2C, 3A to 3C, 4A to 4C, and 5A to 5C are partial vertical cross-section diagrams showing a manufacturing process of the high voltage MOS transistor in accordance with the first embodiment of the present invention. A manufacturing process of a 20 V voltage resistant MOS transistor is hereinafter described.

As shown in FIG. 1A, a field oxide film 120 is formed in an element isolation region of a p-type single crystal silicon substrate 100 with a local oxidation of silicon (LOCOS) method, and an active region 1000 is defined by the field oxide film 120. The active region 1000 is the region to form a high voltage MOS transistor. Then, a gate oxide film 101 of 500 Å in thickness is formed in the active region 1000 of the p-type single crystal silicon substrate 100.

As shown in FIG. 1B, a polysilicon film 102 of 1500 Å in thickness is formed on the gate oxide film 101 and the field oxide film 120 with a heretofore known CVD method.

As shown in FIG. 1C, a silicon nitride film 103 is formed on the polysilicon film 102 with a heretofore known CVD method.

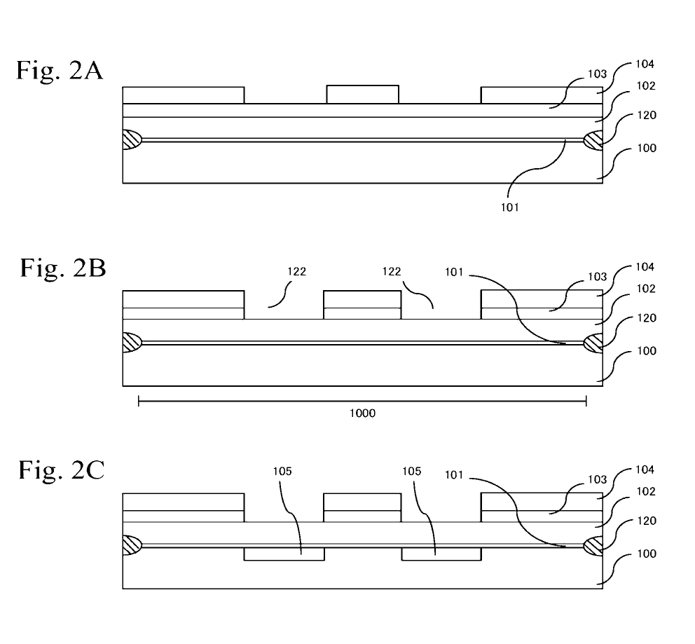

As shown in FIG. 2A, a first resist pattern 104 is formed on the silicon nitride film 103 with a heretofore known lithography technique.

As shown in FIG. 2B, the silicon nitride film 103 is selectively eliminated with etching by using the first resist pattern 104 as a mask. As a result, an opening 122 of 0.5 μm in width is formed in the silicon nitride film 103. Here, the region in which the opening 122 is formed is the region in which an electric field reduction layer overlapping with an edge vicinity of a gate electrode in a self-alignment fashion will be formed. The opening 122 is formed to extend in the width direction of a channel and at least crosses an active pattern. Here, the active pattern means the pattern defined by the boundary between the active region 1000 and the field oxide film 120. In other words, the opening 122 is formed in the width direction of the channel to be extended to a portion of the field oxide film 120. It should be understood that FIG. 2B is a cross-section diagram along with the length direction of the channel and thus this structure is not shown in the diagram.

As shown in FIG. 2C, the n-type impurity phosphorus (P) is selectively implanted into the principal surface of the p-type single crystal silicon substrate 100 through the polysilicon film 102 and the gate oxide film 101 by using the first resist pattern 104 and the silicon nitride film 103 as a mask with an acceleration energy of 220 keV and the dose amount of 6.0×10¹² cm⁻². As a result, a first lightly doped N⁻ diffusion layer 105 is selectively formed in an upper region of the p-type single crystal silicon substrate 100 below the opening 122. Also, the width and the impurity concentration of the first lightly doped N⁻ diffusion layer can be arbitrarily set according to a voltage resistant specification of an embedded device.

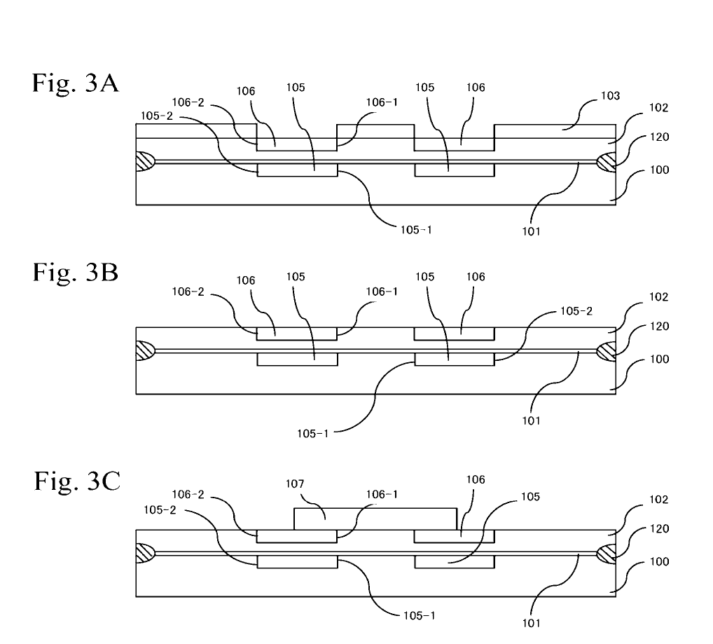

As shown in FIG. 3A, the first resist pattern 104 is eliminated with a heretofore known method. Then, thermal oxidization is conducted with respect to the surface of the polysilicon film 102, which is exposed through the opening 122 formed in the silicon nitride film 103, by using the silicon nitride film 103 as a mask. Thus a thermal oxide film 106 of 200 Å in thickness is formed in an upper region of the polysilicon film 102 below the opening 122. Here, the first lightly doped N⁻ diffusion layer 105 and the thermal oxide film 106 are self-aligned with each other when seen in a horizontal position, because they are formed by using the silicon nitride film 103 having the opening 122 as a mask. In other words, an inner edge 106-1 of the thermal oxide film 106 is self-aligned with an inner edge 105-1 of the first lightly doped N⁻ diffusion layer 105 when seen in a horizontal position. On the other hand, an outer edge 106-2 of the thermal oxide film 106 is self-aligned with an outer edge 105-2 of the first lightly doped N⁻ diffusion layer 105 when seen in a horizontal position.

As shown in FIG. 3B, the silicon nitride film 103 is eliminated with a heretofore known etching method. As a typical example, thermal phosphoric acid can be used for the etching method.

As shown in FIG. 3C, a second resist pattern 107 is formed on the inner region of the thermal oxide film 106 and the upper region of the polysilicon film 102 that is located between the thermal oxide films 106.

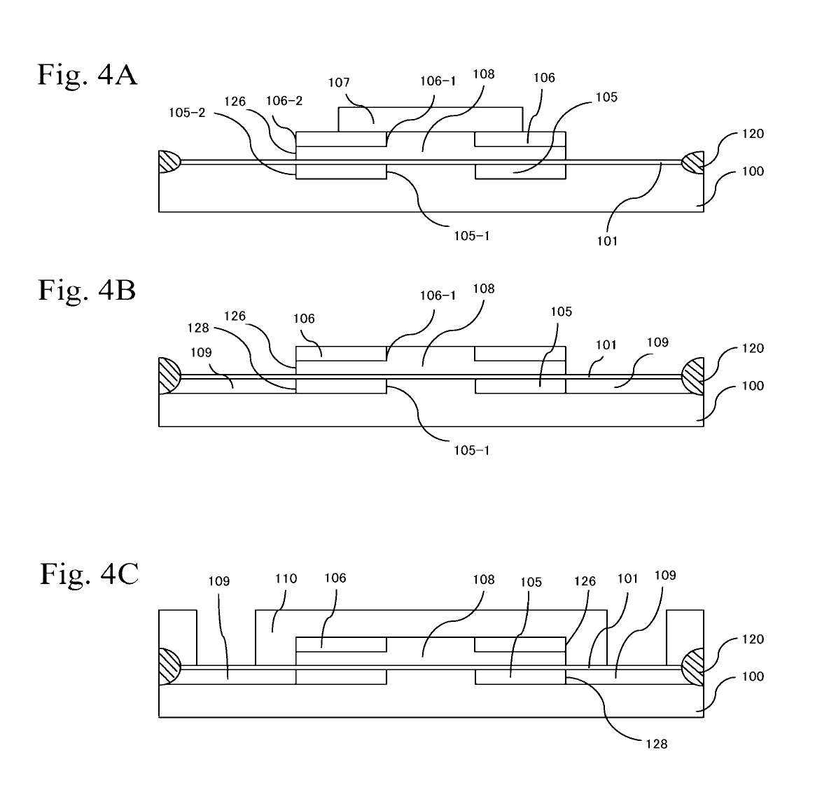

As shown in FIG. 4A, the polysilicon film 102 is selectively etched and eliminated by using the second resist pattern 107 and the thermal oxide film 106 as a mask. As a result, a polysilicon gate electrode 108 is formed. Here, the polysilicon gate electrode 108 has the thermal oxide film 106 in the edge vicinity of its upper region. The polysilicon gate electrode 108 has a gate electrode edge 126, and this gate electrode edge 126 is self-aligned with the outer edge 105-2 of the first lightly doped N⁻ diffusion layer 105 when seen in a horizontal position. Then, the second resist pattern 107 is eliminated with a heretofore known method.

As shown in FIG. 4B, the n-type impurity phosphorus (P) is selectively implanted into the principal surface of the p-type single crystal silicon substrate 100 through the gate oxide film 101 by using the polysilicon gate electrode 108 as a mask with an acceleration energy of 130 keV and the dose amount of 6.0×10¹² cm⁻². As a result, a second lightly doped N⁻ diffusion layer 109 that is self-aligned with the polysilicon gate electrode 108 is selectively formed in an upper region of the p-type single crystal silicon substrate 100, that is, in the region adjacent to the outer side of the first lightly doped N⁻ diffusion layer 105. Here, the outer side of the first lightly doped N⁻ diffusion layer 105 means the region between the first lightly doped N⁻ diffusion layer 105 and the field oxide film 120. As described above, the gate electrode edge 126 is self-aligned with the outer edge 105-2 of the first lightly doped N⁻ diffusion layer 105 when seen in a horizontal position. In addition, the second lightly doped N⁻ diffusion layer 109 is self-aligned with the gate electrode edge 126 when seen in a horizontal position. Therefore, the second lightly doped N⁻ diffusion layer 109 is self-aligned with the inner edge 105-1 of the first lightly doped N⁻ diffusion layer 105 when seen in a horizontal position. That is, a boundary 128 between the first lightly doped N⁻ diffusion layer 105 and the second lightly doped N⁻ diffusion layer 109 is self-aligned with the gate electrode edge 126 when seen in a horizontal position. Also, the first lightly doped N⁻ diffusion layer 105 and the thermal oxide film 106 of the polysilicon gate electrode 108 overlaps with each other in a self-alignment fashion when seen in a horizontal position. That is to say, the first lightly doped N⁻ diffusion layer 105 that functions as an electric field reduction layer and the thermal oxide film 106 that is formed in the edge vicinity of the polysilicon gate electrode 108 overlap with each other in a self-alignment fashion when seen in a horizontal position.

As shown in FIG. 4C, a third resist pattern 110 is formed on the gate electrode 108 and the gate oxide film 101 with a heretofore known lithography technique. Here, the third resist pattern 110 has an opening to expose the surface of a portion of the gate oxide film 101.

As shown in FIG. 5A, the n-type impurity arsenic (AS) is selectively implanted into the second lightly doped N⁻ diffusion layer 109 through the gate oxide film 101 by using the third resist pattern 110 as a mask with an acceleration energy of 40 keV and the dose amount of 5.0×10¹⁵ cm⁻². As a result, a first heavily doped N⁺ diffusion layer 111 is selectively formed in an upper region of the second lightly doped N⁻ diffusion layer 109.

As shown in FIG. 5B, the third resist pattern 110 is eliminated with a heretofore known method.

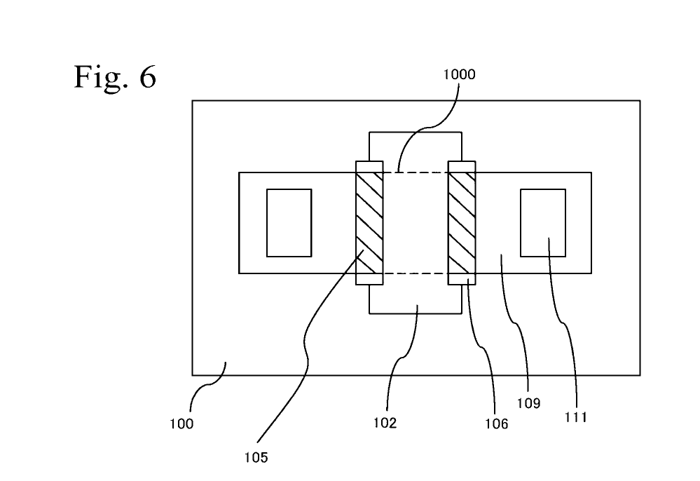

FIG. 6 is a plan view of the structure on the substrate after the third resist pattern 110 is eliminated. It can be seen that the first lightly doped N⁻ diffusion layer 105 and the thermal oxide film 106 formed to be self-aligned with the first lightly doped N⁻ diffusion layer 105 are both formed to cross the active region 1000 along the width direction of a channel. Also, it can be seen that the first lightly doped N⁻ diffusion layer 105 is extended to the boundary between the active region 1000 and the element isolation region, while the thermal oxide film 106 is extended to the element isolation region across the boundary between the active region 1000 and the element isolation region.

As shown in FIG. 5C, an interlayer insulating film 112 is formed on the polysilicon gate electrode 108, the thermal oxide film 106, and the gate oxide film 101 with a heretofore known method. A contact hole is formed in the interlayer insulating film 112 and the gate oxide film 101. Then, a source/drain contact 113 is formed in the contact hole and thus it has an ohmic contact with the first heavily doped N⁺ diffusion layer 111. A source/drain wiring layer 114 is formed on the interlayer insulating film 112 with a heretofore known method, and it is electrically connected to the first heavily doped N⁺ diffusion layer 111 through the source/drain contact 113.

As described above, the first lightly doped N⁻ diffusion layer 105 and the thermal oxide film 106 that defines the gate electrode edge 126 are both formed in a self-alignment fashion by using the pattern comprised of the silicon nitride film 103 as a mask. Furthermore, the second lightly doped N⁻ diffusion layer 109 adjacent to the first lightly doped N⁻ diffusion layer 105 is formed in a self-alignment fashion by using the gate electrode 108 as a mask. As a result, the boundary 128 between the first lightly doped N⁻ diffusion layer 105 and the second lightly doped N⁻ diffusion layer 109 is self-aligned with the gate electrode edge 126 when seen in a horizontal position. Also, the first lightly doped N⁻ diffusion layer 105 functioning as an electric field reduction layer and the thermal oxide film 106 formed in the edge vicinity of the polysilicon gate electrode 108 overlap with each other in a self-alignment fashion when seen in a horizontal position. The following effects are produced by the self-alignment gate overlap structure of the first embodiment of the present invention, in which the first lightly doped N⁻ diffusion layer overlapping with the edge vicinity of the polysilicon gate electrode 108 and functioning as an electric field reduction layer is formed to be self-aligned with the gate electrode edge 126.

First, the overlap dimension between the first lightly doped N⁻ diffusion layer 105 and the gate electrode 108 can be set without any regard for the alignment margin between the patterning to form the first lightly doped N⁻ diffusion layer 105 and the patterning to form the polysilicon gate electrode 108. When the alignment margin is taken into consideration, an overlap dimension of approximately 1.0 μm is needed. For instance, an overlap dimension of approximately 2 μm is needed for a 40 V voltage resistant MOS transistor. However, the gate overlap dimension can be reduced to 0.5 μm according to the gate overlap structure formed in a self-alignment fashion in accordance with the present invention. In other words, when the gate overlap structure is formed in a non-self-alignment fashion, a design value is required to be set to be the dimension derived by adding the above described alignment margin between the patterning to form the first lightly doped N⁻ diffusion layer 105 and the patterning to form the polysilicon gate electrode 108 to the originally necessary gate overlap dimension. On the other hand, the gate overlap structure is formed in a self-alignment fashion, the above described alignment margin between the patternings is not needed and thus a design value can be set to be the originally necessary gate overlap dimension as it is. Because of this, current drive capability of the high voltage MOS transistor can be improved and the device can be miniaturized.

Second, the gate overlap structure formed in a self-alignment fashion in accordance with the present invention can be symmetrically formed based on a channel region when seen in a horizontal position. On the other hand, the gate overlap can be misaligned in the gate overlap structure formed in a non-self-alignment fashion. Because of this, the gate overlap structure can be asymmetrically formed based on a channel region when seen in a horizontal position. As a result, device properties can be varied. However, according to the first embodiment of the present invention, the misalignment of the gate overlap is not caused because the gate overlap structure is formed in a self-alignment fashion. Because of this, the gate overlap structure formed in a self-alignment fashion is symmetrically formed based on a channel region when seen in a horizontal position. As a result, device properties can be reduced and furthermore the defect rate of devices can be improved.

### Second Embodiment

According to the second embodiment of the present invention, a high voltage MOS transistor is provided, which has a lightly doped diffusion layer overlapping with an edge vicinity of a gate electrode in a self-alignment fashion and functioning as an electric field reduction layer. Also, according to the second embodiment of the present invention, a method for manufacturing the high voltage MOS transistor is provided. Also the order of steps of forming a second lightly doped N⁻ diffusion layer and forming a first heavily doped N⁺ diffusion layer is different between the above described first embodiment and the second embodiment of the present invention.

High Voltage MOS Transistor Structure

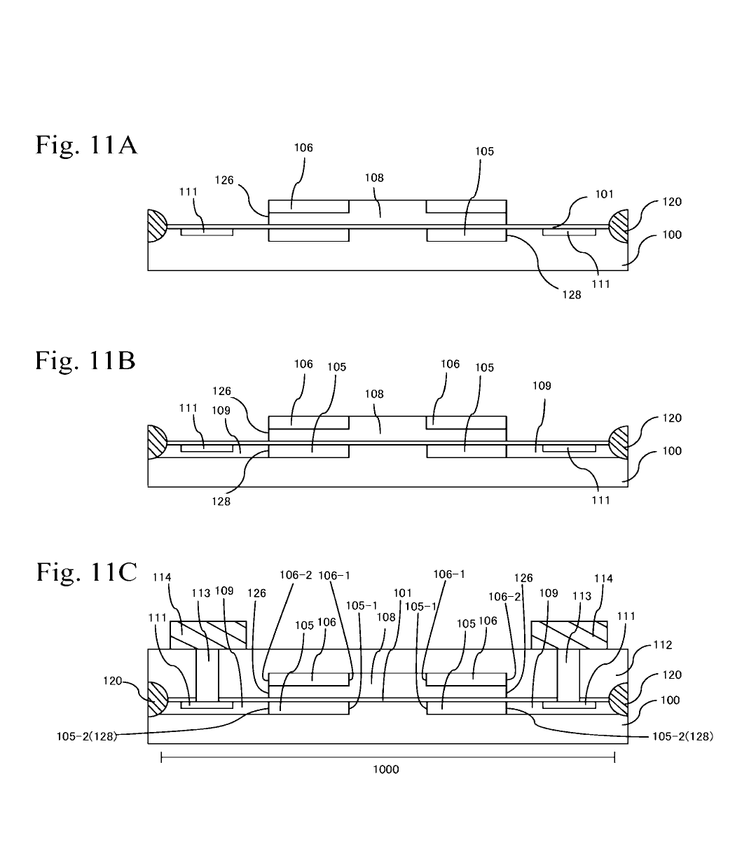

FIG. 11C is a partial cross-section diagram that shows a structure of a high voltage MOS transistor in accordance with the second embodiment of the present invention. The structure of the high voltage MOS transistor in accordance with the second embodiment of the present invention is the same with that of the high voltage MOS transistor in accordance with the first embodiment of the present invention. Therefore, FIG. 11C is also a partial vertical cross-section diagram that shows the structure of a high voltage MOS transistor in accordance with the first embodiment of the present invention.

The high voltage MOS transistor according to the second embodiment of the present invention has the following structure. The principal surface of a p-type single crystal silicon substrate 100 includes an element isolation region comprised of a field oxide film 120 and an active region 1000 defined by the field oxide film 120. A first lightly doped N⁻ diffusion layer 105 and a second lightly doped N⁻ diffusion layer 109 are formed in the active region 1000 of the p-type single crystal silicon substrate 100. The first lightly doped N⁻ diffusion layer 105 and the second lightly doped N⁻ diffusion layer 109 are adjacently formed with each other through a boundary 128. A first heavily doped N⁺ diffusion layer 111 is selectively formed in an upper region of the second lightly doped N⁻ diffusion layer 109. A first heavily doped N⁺ diffusion layer 111 is separated from the first lightly doped N⁻ diffusion layer 105 through the second lightly doped N⁻ diffusion layer 109. The first lightly doped N⁻ diffusion layers 105 are mutually separated through a channel region comprised of a selection upper region of the p-type single crystal silicon substrate 100.

A gate oxide film 101 is formed on the principal surface of the p-type single crystal silicon substrate 100. In other words, a gate oxide film 101 is continuously formed on a first lightly doped N⁻ diffusion layer 105, a second lightly doped N⁺ diffusion layer 109, and a first heavily doped N⁺ diffusion layer 111. A polysilicon gate electrode 108 is selectively formed on a gate oxide film 101. A thermal oxide film 106 is formed in the vicinity of the edge of the upper region (hereinafter called an edge vicinity) of the polysilicon gate electrode 108. The thermal oxide film 106 is self-aligned with the first lightly doped N⁻ diffusion layer 105 when seen in a horizontal position. In other words, an inner edge 106-1 of the thermal oxide film 106 is self-aligned with an inner edge 105-1 of the first lightly doped N⁻ diffusion layer 105 when seen in a horizontal position. On the other hand, an outer edge 106-2 of the thermal oxide film 106 is self-aligned with an outer edge 105-2 of the first lightly doped N⁻ diffusion layer 105 when seen in a horizontal position. A gate electrode edge 126 of the polysilicon gate electrode 108 is self-aligned with the outer edge 106-2 of the thermal oxide film 106 when seen in a horizontal position. Also, the boundary 128 between the first lightly doped N⁻ diffusion layer 105 and the second lightly doped N⁻ diffusion layer 109 corresponds to the outer edge 105-2 of the first lightly doped N⁺ diffusion layer 105. Therefore, the gate electrode edge 126 of the polysilicon gate electrode 108 is self-aligned with the boundary 128 between the first lightly doped N⁺ diffusion layer 105 and the second lightly doped N⁻ diffusion layer 109 when seen in a horizontal position. In other words, the first lightly doped N⁻ diffusion layer 105 overlaps with the polysilicon gate electrode 108 in a self-alignment fashion and thus functions as an electric field reduction layer.

An interlayer insulating film 112 is formed on the polysilicon gate electrode 108, the thermal oxide film 106, and the gate oxide film 101. A source/drain contact 113 is formed in a contact hole formed in the interlayer insulating film 112. The source/drain contact 113 has an ohmic contact with the first heavily doped N⁺ diffusion layer 111. A source/drain wiring layer 114 is formed on the interlayer insulating film 112 and electrically connected to the first heavily doped N⁺ diffusion layer 111 through the source/drain contact 113.

The following is the main structural difference between heretofore known high voltage MOS transistors and the high voltage MOS transistor in accordance with the second embodiment of the present invention. The high voltage MOS transistor in accordance with the second embodiment of the present invention has a structure in which the first lightly doped N⁻ diffusion layer 105 overlaps with the polysilicon gate electrode 108 in a self-alignment fashion.

Method For Manufacturing High Voltage MOS Transistor

With reference to attached figures, a method for manufacturing the high voltage MOS transistor in accordance with the second embodiment of the present invention is hereinafter explained.

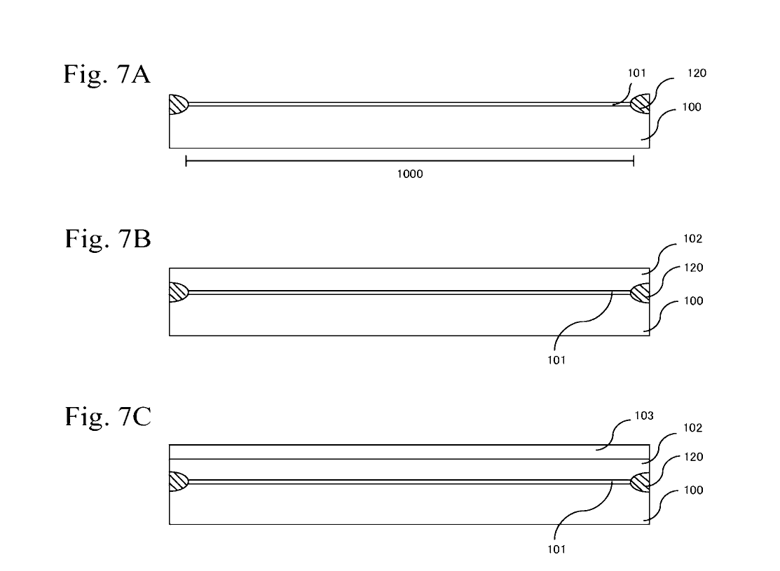

FIGS. 7A to 7C, 8A to 8C, 9A to 9C, 10A to 10C, and 11A to 11C are partial vertical cross-section diagrams showing a manufacturing process of the high voltage MOS transistor in accordance with the second embodiment of the present invention. A manufacturing process of a 20 V voltage resistant MOS transistor is hereinafter described.

As shown in FIG. 7A, a field oxide film 120 is formed in an element isolation region of a p-type single crystal silicon substrate 100 with a local oxidation of silicon (LOCOS) method, and an active region 1000 is defined by the field oxide film 120. The active region 1000 is the region to form a high voltage MOS transistor. Then, a gate oxide film 101 of 500 Å in thickness is formed in the active region 1000 of the p-type single crystal silicon substrate 100.

As shown in FIG. 7B, a polysilicon film 102 of 1500 Å in thickness is formed on the gate oxide film 101 and the field oxide film 120 with a heretofore known CVD method.

As shown in FIG. 7C, a silicon nitride film 103 is formed on the polysilicon film 102 with a heretofore known CVD method.

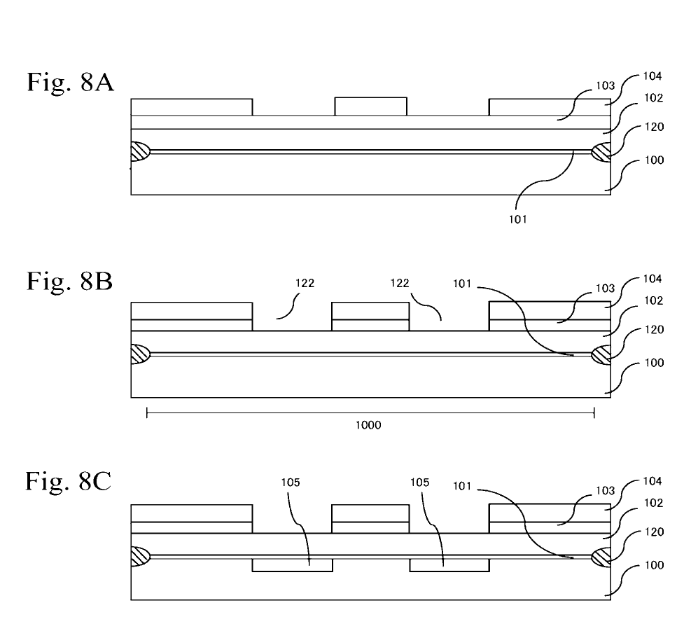

As shown in FIG. 8A, a first resist pattern 104 is formed on the silicon nitride film 103 with a heretofore known lithography technique.

As shown in FIG. 8B, the silicon nitride film 103 is selectively eliminated by with etching by using the first resist pattern 104 as a mask. As a result, an opening 122 of 0.5 μm in width is formed in the silicon nitride film 103. Here, the region in which the opening 122 is formed is the region in which an electric field reduction layer overlapping with an edge vicinity of a gate electrode in a self-alignment fashion will be formed. The opening 122 is formed to extend in the width direction of a channel and at least crosses an active pattern. Here, the active pattern means the pattern defined by the boundary between the active region 1000 and the field oxide film 120. In other words, the opening 122 is formed in the width direction of the channel to be extended to a portion of the field oxide film 120. It should be understood that FIG. 8B is a cross-section diagram along with the length direction of the channel and thus this structure is not shown in the diagram.

As shown in FIG. 8C, the n-type impurity phosphorus (P) is selectively implanted into the principal surface of the p-type single crystal silicon substrate 100 through the polysilicon film 102 and the gate oxide film 101 by using the resist pattern 104 and the silicon nitride film 103 as a mask with an acceleration energy of 220 keV and the dose amount of 6.0×10¹² cm⁻². As a result, a first lightly doped N⁻ diffusion layer 105 is selectively formed in an upper region of the p-type single crystal silicon substrate 100 below the opening 122. Also, the width and the impurity concentration of the first lightly doped N⁻ diffusion layer can be arbitrarily set according to a voltage resistant specification of an embedded device.

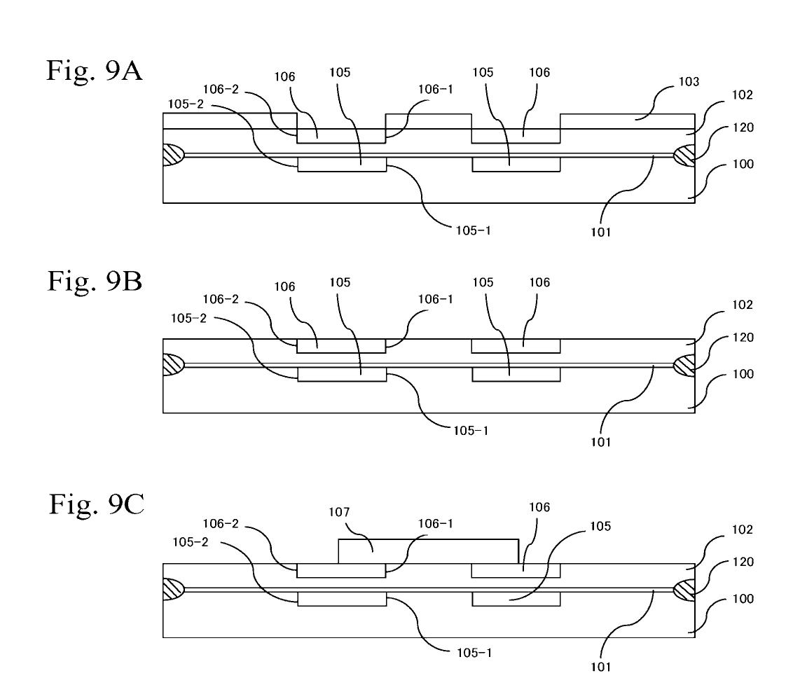

As shown in FIG. 9A, the first resist pattern 104 is eliminated with a heretofore known method. Then, thermal oxidization is conducted with respect to the surface of the polysilicon film 102, which is exposed through the opening 122 formed in the silicon nitride film 103, by using the silicon nitride film 103 as a mask. Thus, a thermal oxide film 106 of 200 Å in thickness is formed in an upper region of the polysilicon film 102 below the opening 122. Here, the first lightly doped N⁻ diffusion layer 105 and the thermal oxide film 106 are self-aligned with each other when seen in a horizontal position, because they are formed by using the silicon nitride film 103 having the opening 122 as a mask. In other words, an inner edge 106-1 of the thermal oxide film 106 is self-aligned with an inner edge 105-1 of the first lightly doped N⁻ diffusion layer 105 when seen in a horizontal position. On the other hand, an outer edge 106-2 of the thermal oxide film 106 is self-aligned with an outer edge 105-2 of the first lightly doped N⁻ diffusion layer 105 when seen in a horizontal position.

As shown in FIG. 9B, the silicon nitride film 103 is eliminated with a heretofore known etching method. As a typical example, thermal phosphoric acid can be used for the etching method.

As shown in FIG. 9C, a second resist pattern 107 is formed on the inner region of the thermal oxide film 106 and the upper region of the polysilicon film 102 that is located between the thermal oxide films 106.

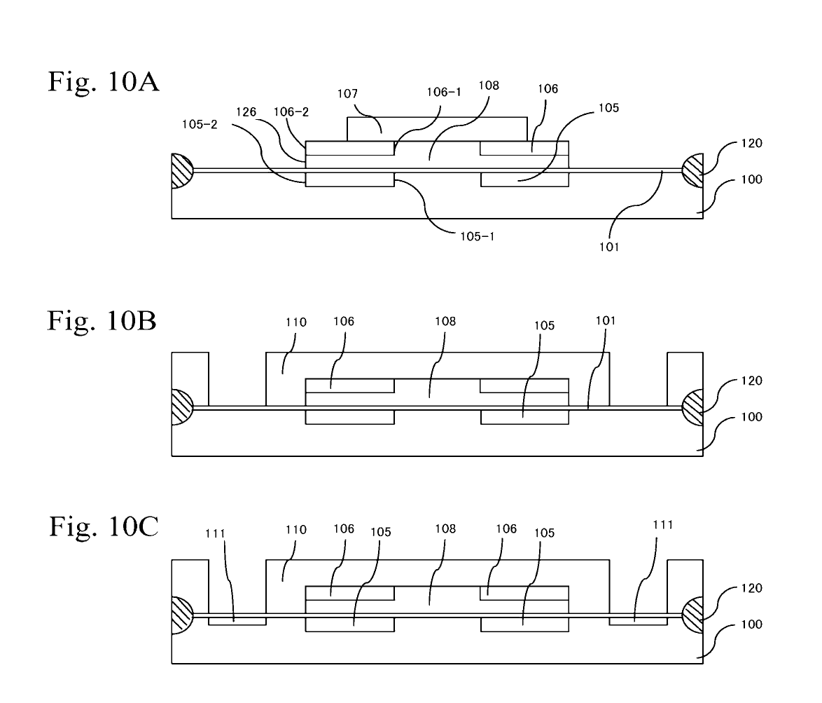

As shown in FIG. 10A, a polysilicon film 102 is selectively etched and eliminated by using the second resist pattern 107 and the thermal oxide film 106 as a mask. As a result, a polysilicon gate electrode 108 is formed. Here, the polysilicon gate electrode 108 has the thermal oxide film 106 in the edge vicinity of its upper region. The polysilicon gate electrode 108 has a gate electrode edge 126, and this gate electrode edge 126 is self-aligned with the outer edge 105-2 of the first lightly doped N⁻ diffusion layer 105 when seen in a horizontal position.

As shown in FIG. 10B, after the second resist pattern 107 is eliminated, a third resist pattern 110 is formed on the gate electrode 108 and the gate oxide film 101 with a heretofore known lithography technique. Here, the third resist pattern 110 has an opening to expose the surface of a portion of the gate oxide film 101.

As shown in FIG. 10C, the n-type impurities arsenic (AS) is selectively implanted into an upper region of the p-type single crystal silicon substrate 100 through the gate oxide film 101 by using the third resist pattern 110 as a mask with an acceleration energy of 40 keV and the dose amount of 5.0×10¹⁵ cm⁻². As a result, a first heavily doped N⁺ diffusion layer 111 is selectively formed in an upper region of the p-type single crystal silicon substrate 100.

As shown in FIG. 11A, the third resist pattern 110 is eliminated with a heretofore known method.

As shown in FIG. 11B, the n-type impurity phosphorus (P) is selectively implanted into the principal surface of the p-type single crystal silicon substrate 100 through the gate oxide film 101 by using the polysilicon gate electrode 108 as a mask with an acceleration energy of 130 keV and the dose amount of 6.0×10¹² cm⁻². As a result, a second lightly doped N⁻ diffusion layer 109 that is self-aligned with the polysilicon gate electrode 108 is selectively formed in an upper region of the p-type single crystal silicon substrate 100, that is, in the region adjacent to the outer side of the first lightly doped N⁻ diffusion layer 105. Here, the outer side of the first lightly doped N⁻ diffusion layer 105 means the region between the first lightly doped N⁻ diffusion layer 105 and the field oxide film 120. Also, as a result, the first heavily doped N⁺ diffusion layer 111 is located in an upper region of the second lightly doped N⁻ diffusion layer 109. As described above, the gate electrode edge 126 is self-aligned with the outer edge 105-2 of the first lightly doped N⁻ diffusion layer 105 when seen in a horizontal position. In addition, the second lightly doped N⁻ diffusion layer 109 is self-aligned with the gate electrode edge 126 when seen in a horizontal position. Therefore, the second lightly doped N⁻ diffusion layer 109 is self-aligned with the inner edge 105-1 of the first lightly doped N⁻ diffusion layer 105 when seen in a horizontal position. That is, a boundary 128 between the first lightly doped N⁻ diffusion layer 105 and the second lightly doped N⁻ diffusion layer 109 is self-aligned with the gate electrode edge 126 when seen in a horizontal position. Also, the first lightly doped N⁺ diffusion layer 105 and the thermal oxide film 106 of the polysilicon gate electrode 108 overlaps with each other in a self-alignment fashion when seen in a horizontal position. That is to say, the first lightly doped N⁻ diffusion layer 105 that functions as an electric field reduction layer and the thermal oxide film 106 that is formed in the edge vicinity of the polysilicon gate electrode 108 overlap with each other in a self-alignment fashion when seen in a horizontal position.

As shown in FIG. 11C, an interlayer insulating film 112 is formed on the polysilicon gate electrode 108, the thermal oxide film 106, and the gate oxide film 101 with a heretofore known lithography technique. A contact hole is formed in the interlayer insulating film 112 and the gate oxide film 101. Then, a source/drain contact 113 is formed in the contact hole and thus it has an ohmic contact with the first heavily doped N⁺ diffusion layer 111. A source/drain wiring layer 114 is formed on the interlayer insulating film 112 with a heretofore known method and it is electrically connected to the first heavily doped N⁺ diffusion layer 111 through the source/drain contact 113.

In the second embodiment of the present invention, the first heavily doped N⁺ diffusion layer is formed before the second lightly doped N⁻ diffusion layer is formed. Therefore, the order of forming these layers is different between the first and the second embodiments. In the second embodiment of the present invention, the first lightly doped N⁻ diffusion layer 105 and the thermal oxide film 106 that defines the gate electrode edge 126 are both formed in a self-alignment fashion by using the pattern comprised of the silicon nitride film 103 as a mask. Furthermore, the second lightly doped N⁻ diffusion layer 109 adjacent to the first lightly doped N⁻ diffusion layer 105 is formed in a self-alignment fashion by using the gate electrode 108 as a mask. As a result, the boundary 128 between the first lightly doped N⁻ diffusion layer 105 and the second lightly doped N⁻ diffusion layer 109 are self-aligned with the gate electrode edge 126 when seen in a horizontal position. Also, the first lightly doped N⁻ diffusion layer 105 that functions as an electric field reduction layer and the thermal oxide film 106 that is formed in the edge vicinity of the polysilicon gate electrode 108 overlap with each other in a self-alignment fashion when seen in a horizontal position. The first lightly doped N⁻ diffusion layer that overlaps with the edge vicinity of the polysilicon gate electrode 108 and functions as an electric field reduction layer is formed to be self-aligned with the gate electrode edge 126. Therefore, the self-alignment gate overlap structure in accordance with the second embodiment of the present invention has the identical effects with those of the self-alignment gate overlap structure in accordance with the above described first embodiment.

### Third Embodiment

According to the third embodiment of the present invention, a high voltage MOS transistor is provided, which has a lightly doped diffusion layer overlapping with an edge vicinity of a gate electrode in a self-alignment fashion and functioning as an electric field reduction layer. Also, according to the third embodiment of the present invention, a method for manufacturing the high voltage MOS transistor is provided. The third embodiment is different from the above described first and second embodiments in that not only the second lightly doped N⁻ diffusion layer but also the first heavily doped N⁺ diffusion layer is self-aligned with the gate electrode.

High Voltage MOS Transistor Structure

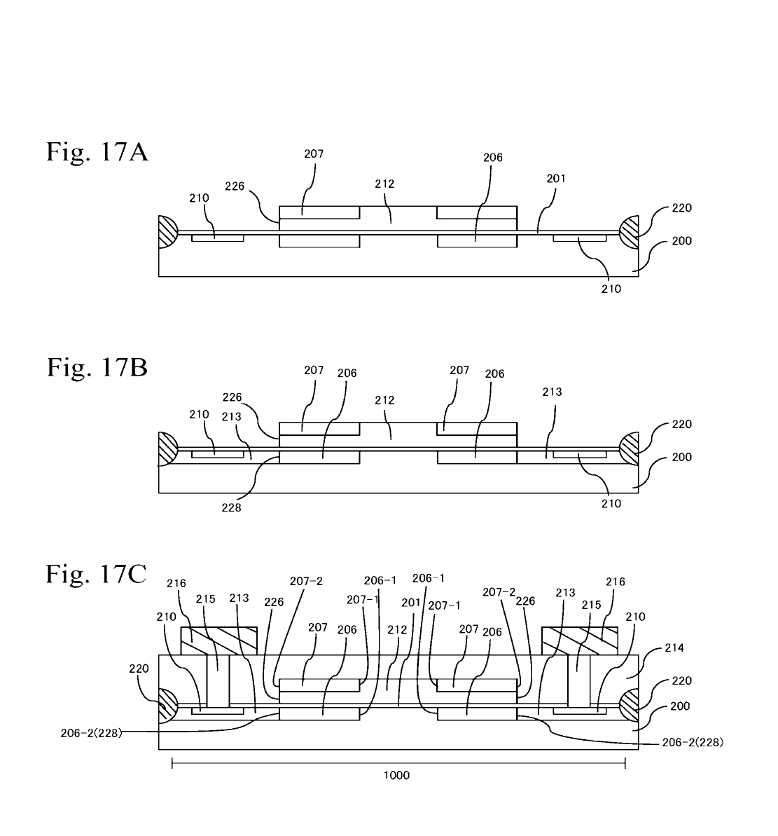

FIG. 17C is a partial vertical cross-section diagram that shows the structure of a high voltage MOS transistor in accordance with the third embodiment of the present invention.

The high voltage MOS transistor according to the third embodiment of the present invention has the following structure. The principal surface of a p-type single crystal silicon substrate 200 includes an element isolation region comprised of a field oxide film 220 and an active region 1000 defined by the field oxide film 220. A first lightly doped N⁻ diffusion layer 206 and a second lightly doped N⁻ diffusion layer 213 are adjacently formed through a boundary 228 in the active region 1000 of the p-type single crystal silicon substrate 200. A heavily doped N diffusion layer 210 is selectively formed in an upper region of the second lightly doped N⁻ diffusion layer 213. The first heavily doped N⁺ diffusion layer 210 is separated from the first lightly doped N⁻ diffusion layer 206 through the second lightly doped N⁻ diffusion layer 213. The first lightly doped N⁻ diffusion layers 206 are separated through a channel region comprised of a selective upper region of the p-type single crystal silicon substrate 200.

A gate oxide film 201 is formed on the principal surface of the p-type single crystal silicon substrate 200. In other words, a gate oxide film 201 is continuously formed on the first lightly doped N⁻ diffusion layer 206, the second lightly doped N⁺ diffusion layer 213, and the first heavily doped N diffusion layer 210. A polysilicon gate electrode 212 is selectively formed on the gate oxide film 201. A thermal oxide film 207 is formed in the vicinity of the edge of the upper region (hereinafter called an edge vicinity) of the polysilicon gate electrode 212. The thermal oxide film 207 is self-aligned with the first lightly doped N⁻ diffusion layer 206 when seen in a horizontal position. In other words, an inner edge 207-1 of the thermal oxide film 207 is self-aligned with an inner edge 206-1 of the first lightly doped N⁻ diffusion layer 206 when seen in a horizontal position. On the other hand, an outer edge 207-2 of the thermal oxide film 207 is self-aligned with an outer edge 206-2 of the first lightly doped N⁻ diffusion layer 206 when seen in a horizontal position. A gate electrode edge 126 of the polysilicon gate electrode 212 is self-aligned with the outer edge 207-2 of the thermal oxide film 207 when seen in a horizontal position. Also, the boundary 228 between the first lightly doped N⁻ diffusion layer 206 and the second lightly doped N⁺ diffusion layer 213 corresponds to the outer edge 206-2 of the first lightly doped N⁺ diffusion layer 206. Therefore, a gate electrode edge 226 of the polysilicon gate electrode 212 is self-aligned with the boundary 228 between the first lightly doped N⁺ diffusion layer 206 and the second lightly doped N⁻ diffusion layer 213 when seen in a horizontal position. In other words, the first lightly doped N⁻ diffusion layer 206 overlaps with the polysilicon gate electrode 212 in a self-alignment fashion and thus functions as an electric field reduction layer. Furthermore, the first heavily doped N⁺ diffusion layer 210 is offset from the polysilicon gate electrode 212 in a self-alignment fashion.

An interlayer insulating film 214 is formed on the polysilicon gate electrode 212, the thermal oxide film 207, and the gate oxide film 201. A source/drain contact 215 is formed in a contact hole formed in the interlayer insulating film 214. The source/drain contact 215 has an ohmic contact with the first heavily doped N⁺ diffusion layer 210. A source/drain wiring layer 216 is formed on the interlayer insulating film 214 and electrically connected to the first heavily doped N⁺ diffusion layer 210 through the source/drain contact 215.

The following is the main structural difference between heretofore known high voltage MOS transistors and the high voltage MOS transistor in accordance with the third embodiment of the present invention. The high voltage MOS transistor in accordance with the third embodiment of the present invention has a structure in which the first lightly doped N⁻ diffusion layer 206 overlaps with the polysilicon gate electrode 212 in a self-alignment fashion. Furthermore, the high voltage MOS transistor in accordance with the third embodiment has a structure in which the first heavily doped N⁺ diffusion layer 210 is offset from the polysilicon gate electrode 212 in a self-alignment fashion.

Method For Manufacturing High Voltage MOS Transistor

With reference to attached figures, a method for manufacturing the high voltage MOS transistor in accordance with the third embodiment of the present invention is hereinafter explained.

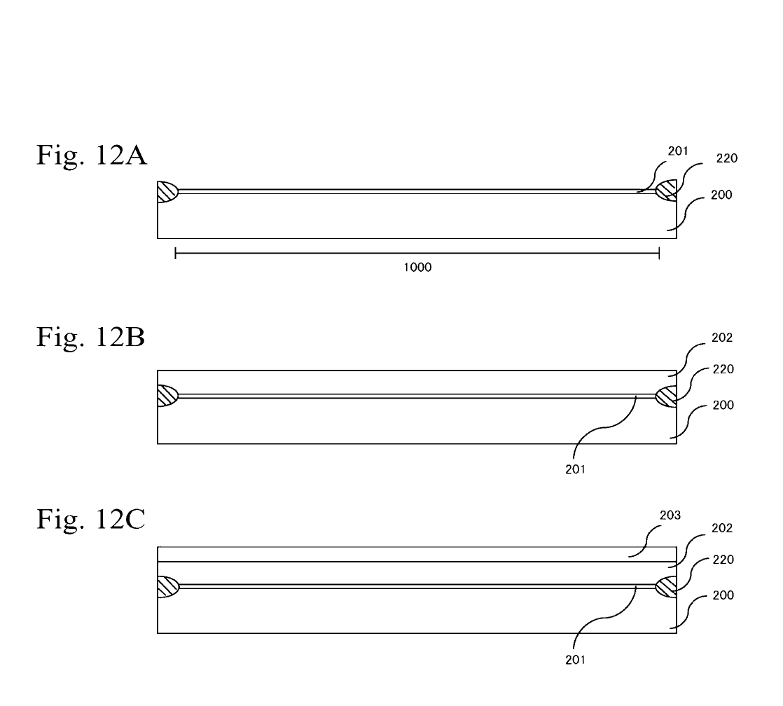

FIGS. 12A to 12C, 13A to 13C, 14A to 14C, 15A to 15C, 16A to 16C, and 17A to 17C are partial vertical cross-section diagrams showing a manufacturing process of the high voltage MOS transistor in accordance with the third embodiment of the present invention. A manufacturing process of a 20 V voltage resistant MOS transistor is hereinafter described.

As shown in FIG. 12A, a field oxide film 220 is formed in an element isolation region of a p-type single crystal silicon substrate 200 with a local oxidation of silicon (LOCOS) method, and an active region 1000 is defined by the field oxide film 220. The active region 1000 is the region to form a high voltage MOS transistor. Then, a gate oxide film 201 of 500 Å in thickness is formed in the active region 1000 of the p-type single crystal silicon substrate 200.

As shown in FIG. 12B, a polysilicon film 202 of 1500 Å in thickness is formed on the gate oxide film 201 and the field oxide film 220 with a heretofore known CVD method.

As shown in FIG. 12C, a silicon nitride film 203 of 2000 Å in thickness is formed on the polysilicon film 202 with a heretofore known CVD method.

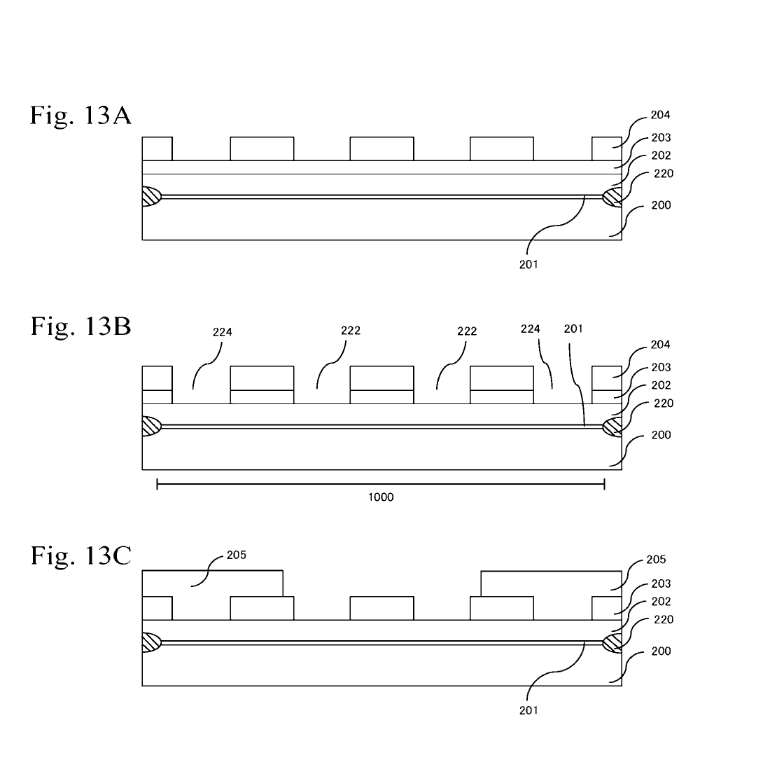

As shown in FIG. 13A, a first resist pattern 204 is formed on the silicon nitride film 203 with a heretofore known lithography technique.

As shown in FIG. 13B, the silicon nitride film 203 is selectively eliminated with etching by using the first resist pattern 204 as a mask. As a result, openings 222 and 224 are formed in the silicon nitride film 203.

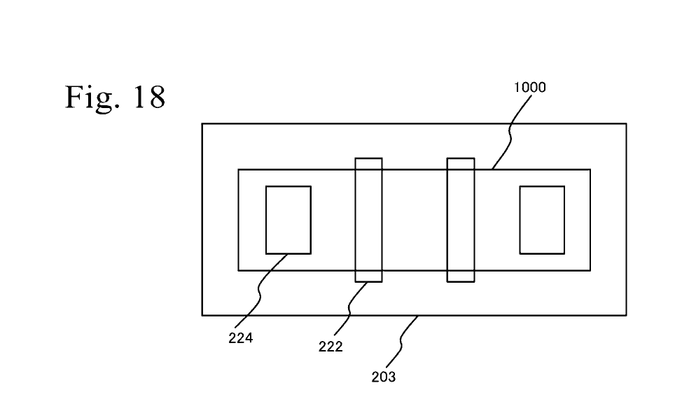

FIG. 18 shows the openings 222 and 224 formed in the pattern comprised of the silicon nitride film 203. Here, the region in which the opening 222 is formed is the region in which an electric field reduction layer overlapping with an edge vicinity of a gate electrode in a self-alignment fashion will be formed. On the other hand, the region in which the opening 224 is formed is the region in which a heavily doped diffusion layer will be formed. The opening 222 is formed to extend in the width direction of a channel and at least crosses an active pattern. Here, the active pattern means the pattern defined by the boundary between the active region 1000 and the field oxide film 220. In other words, the opening 222 is formed in the width direction of the channel to be extended to a portion of the field oxide film 220. On the other hand, the opening 224 is formed to be included within the active pattern. The width of the opening 222 is 0.5 μm. Here, the width of the opening 222 is the dimension of the opening 222 in the channel length direction. Also, the distance between the opening 222 and the opening 224 is 2.0 μm, for instance.

As shown in FIG. 13C, the first resist pattern 204 is eliminated with a heretofore known method. Then, a second resist pattern 205 is formed on the silicon nitride film 203 to fill the interior of the opening 224.

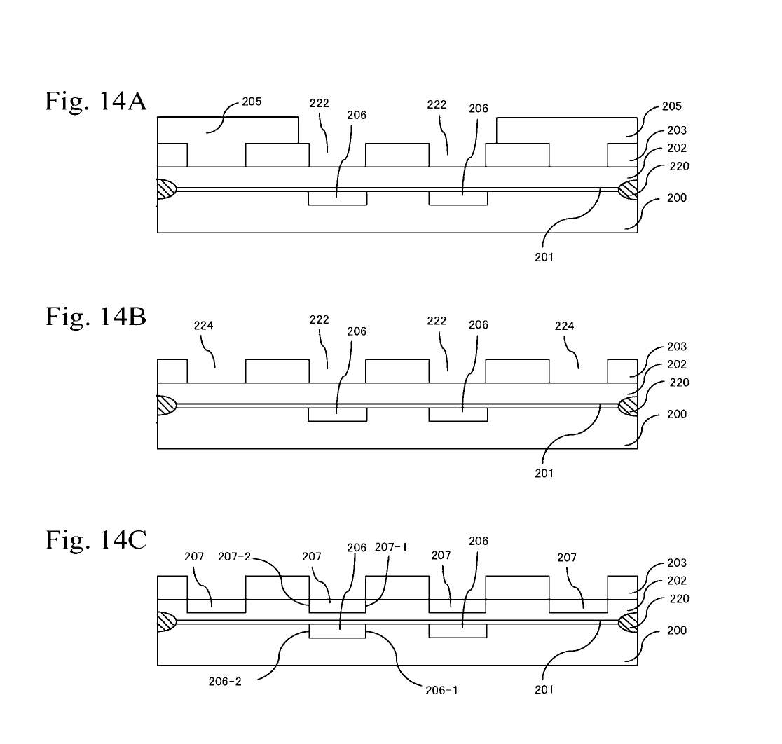

As shown in FIG. 14A, the n-type impurity phosphorus (P) is selectively implanted into the principal surface of the p-type single crystal silicon substrate 200 through the polysilicon film 202 and the gate oxide film 201 by using the second resist pattern 205 and the silicon nitride film 203 as a mask with an acceleration energy of 220 keV and the dose amount of 6.0×10¹² cm⁻². As a result, a first lightly doped N⁺ diffusion layer 206 is selectively formed in an upper region of the p-type single crystal silicon substrate 200 below the opening 222. Also, the width and the impurity concentration of the first lightly doped N⁻ diffusion layer 206 can be arbitrarily set according to a voltage resistant specification of an embedded device.

As shown in FIG. 14B, the second resist pattern 205 is eliminated with a heretofore known method.

As shown in FIG. 14C, thermal oxidization is conducted with respect to the surface of the polysilicon film 202, which is exposed through the openings 222 and 224 formed in the silicon nitride 203, by using the silicon nitride film 203 as a mask. Thus, a thermal oxide film 207 of 200 Å in thickness is formed in an upper region of the polysilicon film 202 immediately below the openings 222 and 224. Here, the first lightly doped N⁻ diffusion layer 206 and the thermal oxide film 207 are self-aligned with each other when seen in a horizontal position, because they are formed by using the silicon nitride film 203 having the openings 222 and 224 as a mask. In other words, an inner edge 207-1 of the thermal oxide film 207 is self-aligned with an inner edge 206-1 of the first lightly doped N⁻ diffusion layer 206 when seen in a horizontal position. On the other hand, an outer edge 207-2 of the thermal oxide film 207 is self-aligned with an outer edge 206-2 of the first lightly doped N⁻ diffusion layer 206 when seen in a horizontal position.

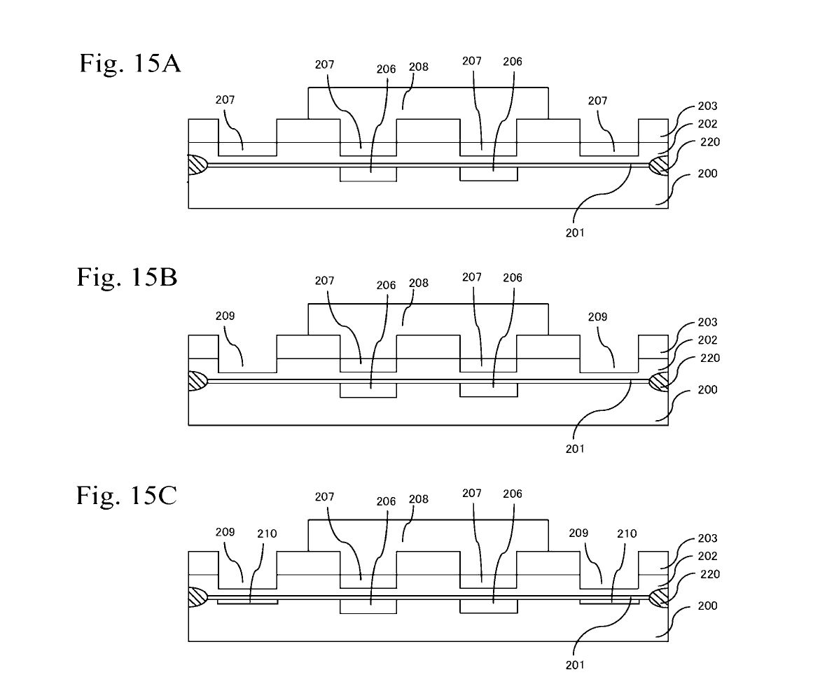

As shown in FIG. 15A, a third resist pattern 208 is formed on the silicon nitride film 203 to fill the interior of the opening 222 with a heretofore known lithography technique.

As shown in FIG. 15B, the thermal oxide film 207 formed immediately below the opening 224 is eliminated with an etching method by using the resist pattern 208 and the silicon nitride film 203 as a mask, and thus an opening 209 is formed. As a typical example, hydrofluoric acid can be used for the etching method.

As shown in FIG. 15C, the n-type impurity phosphorus (P) is selectively implanted into the principal surface of the p-type single crystal silicon substrate 200 through the polysilicon film 202 and the gate oxide film 201 by using the resist pattern 208 and the silicon nitride film 203 as a mask with an acceleration energy of 100 keV and the dose amount of 1.0×10₁₅ cm⁻². As a result, a first heavily doped N⁺ diffusion layer 210 is selectively formed in an upper region of the p-type single crystal silicon substrate 200 below the opening 209. Here, the above described first lightly doped N⁺ diffusion layer 206 and the first heavily doped N⁺ diffusion layer 210 are both formed by using the pattern comprised of the silicon nitride film 203 as a mask. Therefore, the first heavily doped N⁺ diffusion layer 210 is offset from the above described first lightly doped N⁻ diffusion layer 206 and a gate electrode 212 described below in a self-alignment fashion.

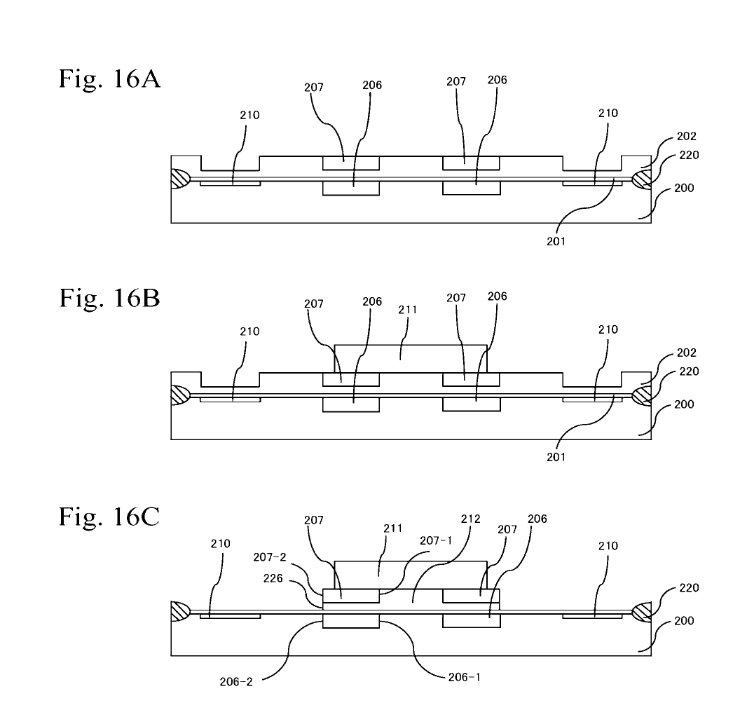

As shown in FIG. 16A, the resist pattern 208 is eliminated with a heretofore known method. In addition, the silicon nitride film 203 is eliminated by a heretofore known etching method. As a typical example, thermal phosphoric acid is used for the etching method.

As shown in FIG. 16B, a fourth resist pattern 211 is formed on an inner region of the thermal oxide film 207 and an upper region of the polysilicon film 202 formed that is located between the thermal oxide films 207.

As shown in FIG. 16C, the polysilicon film 202 is selectively etched and eliminated by using the resist pattern 211 and the thermal oxide film 207 as a mask. As a result, a polysilicon gate electrode 212 is formed. Here, the polysilicon gate electrode 212 has the thermal oxide film 207 in an edge vicinity of its upper region. The polysilicon gate electrode 212 has a gate electrode edge 226, and this gate electrode edge 226 is self-aligned with the outer edge 206-2 of the first lightly doped N⁻ diffusion layer 206 when seen in a horizontal position. Also, the first heavily doped N⁺ diffusion layer 210 is self-aligned with the polysilicon gate electrode 212 because the thermal oxide film 207 that defines the gate electrode edge 226 and the first heavily doped N⁺ diffusion layer 210 are both formed by using the pattern comprised of the silicon nitride film 203 as a mask.

As shown in FIG. 17A, the fourth resist pattern 211 is eliminated with a heretofore known method.

As shown in FIG. 17B, the n-type impurity phosphorus (P) is selectively implanted into the principal surface of the p-type single crystal silicon substrate 200 through the gate oxide film 201 by using the polysilicon gate electrode 212 as a mask with an acceleration energy of 130 keV and the dose amount of 6.0×10¹² cm⁻². As a result, a second lightly doped N⁻ diffusion layer 213, which is self-aligned with the polysilicon gate electrode 212, is selectively formed in an upper region of the p-type single crystal silicon substrate 200, that is, in the region adjacent to the outer side of the first lightly doped N⁻ diffusion layer 206. Here, the outer side of the first lightly doped N⁻ diffusion layer 206 means the region between the first lightly doped N⁻ diffusion layer 206 and the field oxide film 220. Also, as a result, the first heavily doped N⁺ diffusion layer 210 is located in an upper region of the second lightly doped N⁻ diffusion layer 213. As described above, the gate electrode edge 226 is self-aligned with the outer edge 206-2 of the first lightly doped N⁻ diffusion layer 206 when seen in a horizontal position. In addition, the second lightly doped N⁻ diffusion layer 213 is self-aligned with the gate electrode edge 226 when seen in a horizontal position. Therefore, the second lightly doped N⁻ diffusion layer 213 is self-aligned with the inner edge 206-1 of the first lightly doped N⁻ diffusion layer 206 when seen in a horizontal position. That is, a boundary 228 between the first lightly doped N⁻ diffusion layer 206 and the second lightly doped N⁻ diffusion layer 213 is self-aligned with the gate electrode edge 226 when seen in a horizontal position. Also, the first lightly doped N⁺ diffusion layer 206 and the thermal oxide film 207 formed in the polysilicon gate electrode 212 overlaps with each other in a self-alignment fashion when seen in a horizontal position. In other words, the first lightly doped N⁻ diffusion layer 206 that functions as an electric field reduction layer and the thermal oxide film 207 that is located in the edge vicinity of the polysilicon gate electrode 212 overlap with each other in a self-alignment fashion when seen in a horizontal position. Furthermore, as described above, the thermal oxide film 207 that defines the gate electrode edge 226 and the first heavily doped N⁺ diffusion layer 210 are both formed by using the pattern comprised of the silicon nitride film 203 as a mask. Because of this, the first heavily doped N⁺ diffusion layer 210 is offset from the polysilicon gate electrode 212 in a self-alignment fashion. Therefore, the first lightly doped N⁻ diffusion layer 206 overlaps with the polysilicon gate electrode 212 in a self-alignment fashion. In addition, a structure in which the first heavily doped N⁻ diffusion layer 210 is offset from the polysilicon gate electrode 212 in a self-alignment fashion is formed.

As shown in FIG. 17C, an interlayer insulating film 214 is formed on the polysilicon gate electrode 212, the thermal oxide film 207, and the gate oxide film 201 with a heretofore known lithography technique. A contact hole is formed in the interlayer insulating film 214 and the gate oxide film 201. Then, a source/drain contact 215 is formed in the contact hole, and thus it has an ohmic contact with the first heavily doped N⁺ diffusion layer 210. Next, a source/drain wiring layer 216 is formed on the interlayer insulating film 214 with a heretofore known method and electrically connected to the first heavily doped N⁺ diffusion layer 210 through the source/drain contact 215.

In the third embodiment of the present invention, the thermal oxide film 207 that defines the gate electrode edge 226 and the first heavily doped N⁺ diffusion layer 210 are both formed by using the pattern comprised of the silicon nitride film 203 as a mask. Because of this, the first heavily doped N⁺ diffusion layer 210 is offset from the polysilicon gate electrode 212 in a self-alignment fashion. The third embodiment is different from the above described first embodiment in this regard. Therefore, the third embodiment has the following effects in addition to the above described first and second effects of the first embodiment.

Third, the distance between the first doped N⁺ diffusion layer 210 and the gate electrode 212 can be set without any regard for the alignment margin between the patterning to form the first heavily doped N⁺ diffusion layer 210 and the patterning to form the polysilicon gate electrode 212. This is because the first heavily doped N⁺ diffusion layer 210 is self-aligned with the gate electrode 212. When the alignment margin is taken into consideration, the distance between the first heavily doped N⁺ diffusion layer 210 and the gate electrode 212 is required to be set to be at least 2.5 μm. However, according to the structure formed in a self-alignment fashion in accordance with the present invention, the distance between the first heavily doped N⁺ diffusion layer 210 and the gate electrode 212 can be reduced to 2.0 m. In other words, when the first heavily doped N⁺ diffusion layer 210 is formed not to be self-aligned with the gate electrode 212, a design value is required to be set to be the value derived by adding the above described alignment margin between the patterning to form the first heavily doped N⁺ diffusion layer 210 and the patterning to form the polysilicon gate electrode 210 to the originally necessary distance between the first heavily doped N⁺ diffusion layer 210 and the gate electrode 212. On the other hand, when the first heavily doped N⁺ diffusion layer 210 is formed to be self-aligned with the gate electrode 212, the above described alignment margin between those patternings is not needed. Therefore, the design value can be set to be the originally necessary distance between the first heavily doped N⁺ diffusion layer 210 and the gate electrode 212 as it is. Because of this, current drive capability of the high voltage MOS transistor can be further improved. As a result, the device size can be further reduced.

Fourth, the first heavily doped N⁺ diffusion layer 210 can be symmetrically formed with respect to the gate electrode 212 when seen in a horizontal position when the first heavily doped N⁺ diffusion layer 210 is formed to be self-aligned with the gate electrode 212. On the other hand, when the first heavily doped N⁺ diffusion layer 210 is formed not to be self-aligned with the gate electrode 212, the first heavily doped N⁺ diffusion layer 210 can be asymmetrically formed with respect to the gate electrode 212 when seen in a horizontal position. As a result, device properties can be varied. However, according to the present invention, the first heavily doped N⁺ diffusion layer 210 is formed to be self-aligned with the gate electrode 212. Therefore, it is possible to symmetrically form the first heavily doped N⁺ diffusion layer 210 with respect to the gate electrode 212 when seen in a horizontal position. As a result, variations of device properties can be reduced. Furthermore, the defect rate of devices can be greatly improved.

### Other Embodiment

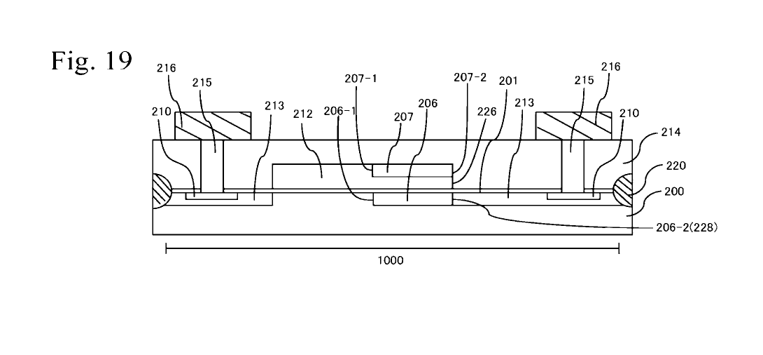

FIG. 19 is a partial vertical cross-section diagram of another type of a high voltage MOS transistor in accordance with the present invention. In the above described first to third embodiments, the gate overlap structure is symmetrical with respect to the gate electrode when seen in a horizontal position. However, the above described gate overlap structure may be formed only on either the source side or the drain side. For example, as shown in FIG. 19, the above described gate overlap structure may be formed only on the drain side.

The high voltage MOS transistor in accordance with the other embodiment has the following structure. The principal surface of a p-type single crystal silicon substrate 200 includes an element isolation region comprised of a field oxide film 220 and an active region 1000 defined by the field oxide film 220. A lightly doped N⁺ diffusion layer 213 is formed both on source and drain sides in an active region 1000 of the p-type single crystal silicon substrate 200. Also, a first lightly doped N⁻ diffusion layer 206 is formed only on the drain side to be located adjacent to the second lightly doped N⁻ diffusion layer 213 formed on the drain side though a boundary 228. A first heavily doped N⁺ diffusion layer 210 is selectively formed in an upper region of the second lightly doped N⁻ diffusion layer 213 formed both on the source and drain regions. The first heavily doped N⁺ diffusion layer 210 formed on the drain side is separated from the first lightly doped N⁻ diffusion layer 206 and the p-type single crystal silicon substrate 200 through the second lightly doped N⁻ diffusion layer 213. The first heavily doped N⁺ diffusion layer 210 formed on the source side is separated from the p-type single crystal silicon substrate 200 through the second lightly doped N⁻ diffusion layer 213. The p-type single crystal silicon substrate 200 has a channel region that is defined between the second lightly doped N⁻ diffusion layer 213 formed on the source side and the first lightly doped N⁻ diffusion layer 206 formed only on the drain side.

A gate oxide film 201 is formed on the principal surface of the p-type single silicon substrate 200. In other words, the gate oxide film 201 is continuously formed on a channel region, the first lightly doped N⁻ diffusion layer 206 formed only on the drain side, the second lightly doped N⁻ diffusion layer 213, and the first heavily doped N⁺ diffusion layer 210. A polysilicon gate electrode 212 is selectively formed on the gate oxide film 201. The thermal oxide film 207 is formed in the edge vicinity on the drain side in an upper region of the polysilicon gate electrode 212. The thermal oxide film 207 is self-aligned with the first lightly doped N⁻ diffusion layer 206 when seen in a horizontal position. In other words, an inner edge 207-1 of the thermal oxide film 207 is self-aligned with an inner edge 206-1 of the first lightly doped N⁻ diffusion layer 206 when seen in a horizontal position. On the other hand, an outer edge 207-2 of the thermal oxide film 207 is self-aligned with an outer edge 206-2 of the first lightly doped N⁻ diffusion layer 206 when seen in a horizontal position. A gate electrode edge 226 of the polysilicon gate electrode 212 is self-aligned with the outer edge 207-2 of the thermal oxide film 207 when seen in a horizontal position. Also, a boundary 228 between the first lightly doped N⁻ diffusion layer 206 and the second lightly doped N⁺ diffusion layer 213 formed on the drain side corresponds to an outer edge 206-2 of the first lightly doped N⁻ diffusion layer 206. Therefore, the gate electrode edge 226 of the polysilicon gate electrode 212 is self aligned with the boundary 228 between the first lightly doped N⁻ diffusion layer 206 and the second lightly doped N⁻ diffusion layer 213 when seen in a horizontal position. In other words, the first lightly doped N⁻ diffusion layer 206 formed only on the drain side overlaps with the polysilicon gate electrode 212 in a self-alignment fashion, and thus the first lightly doped N⁻ diffusion layer 206 functions as an electric field reduction layer. Furthermore, the first heavily doped N⁺ diffusion layer 210 is offset form the polysilicon gate electrode 212 in a self-alignment fashion.

An interlayer insulating film 214 is formed on the polysilicon gate electrode 212, the thermal oxide film 207, and the gate oxide film 201. A source/drain contact 215 is formed in a contact hole of the interlayer insulating film 214. The source/drain contact 215 has an ohmic contact with the first heavily doped N⁺ diffusion layer 210. A source/drain wiring layer 216 is formed on the interlayer insulating film 214, and thus electrically connected to the first heavily doped N⁺ diffusion layer 210 through the source/drain contact 215.

The following are the main structural difference between heretofore known high voltage MOS transistors and the high voltage MOS transistor in accordance with this embodiment. The high voltage MOS transistor in accordance with this embodiment has a structure in which the first lightly doped N⁻ diffusion layer 206 formed only on the drain side overlaps with the polysilicon gate electrode 212 in a self-alignment fashion. Furthermore, it includes a structure in which the first heavily doped N⁻ diffusion layer 210 is offset from the polysilicon gate electrode 212 in a self-alignment fashion.

The above described asymmetrical gate overlap structure has the identical effects to the first to fourth effects of the above described first to third embodiments of the present invention.

The method for manufacturing the above described asymmetrical gate overlap structure is different from the method for manufacturing the gate overlap structure of the above described embodiments in that the first lightly doped N⁻ diffusion layer 206 and the thermal oxide film 207 are formed only on the drain side.

Also, the above described ion implantation means a step of vertically implanting ions into the substrate surface.

Also, the n-type MOSFET is explained in the above described first and second embodiments. However, the present invention can be applied to p-type MOSFETs by using other types of ion species.

Furthermore, the above described gate electrode is comprised of the polysilicon layer including impurities. However, the gate electrode is not limited to this type. An upper region of the above described gate electrode may be comprised of a silicide layer or a salicide (self-aligned silicide) layer to further reduce resistance of the gate electrode.

It should be understood that the above described thickness and impurity concentration of each layer are illustrative only and their design can be changed.

This application claims priority to Japanese Patent Application No. 2005-067575. The entire disclosure of Japanese Patent Application No. 2005-067575 is hereby incorporated herein by reference.

The terms of degree, such as “approximately” and “substantially,” used herein mean a reasonable amount of deviation of the modified term such that the end result is not significantly changed. For example, the terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A method for forming a semiconductor device, comprising the steps of:
forming a gate insulating film above a semiconductor substrate;
forming a first conductive film on said gate insulating film;
forming a first insulating film pattern on said first conductive film;
selectively forming a first impurity diffusion layer in said semiconductor substrate by implanting impurity ions into said semiconductor substrate by using at least said first insulating pattern as a mask;
selectively forming a first selective insulating film that overlaps with said first impurity diffusion layer in a self-alignment fashion in said first conductive film by using said first insulating film pattern as a mask;
forming a gate electrode that has a gate edge self-aligned with said first impurity diffusion layer and that overlaps with said first impurity diffusion layer in a self-alignment fashion, said gate edge being defined by said first selective insulating film by selectively etching said first conductive film by using at least said first selective insulating film as a mask; and
selectively forming a second impurity diffusion layer that is located adjacent to said first impurity diffusion layer and is self-aligned with said gate edge by implanting impurities into said semiconductor substrate by using said gate electrode as a mask.

2. The method according to claim 1,
wherein said conductive film is comprised of a polysilicon film; and
said step of forming said first selective insulating film is comprised of a step of forming a silicon dioxide film by conducting thermal oxidation with respect to the surface of said polysilicon film exposed through said first insulating film pattern.

3. The method according to claim 2, further comprising a step of forming a third impurity diffusion layer that is self-aligned with said first selective insulating film and said first impurity diffusion layer by conducting ion implantation of impurities by using said first insulating film pattern as a mask.

4. The method according to claim 3,
wherein said first insulating film pattern has a first opening corresponding to a region in which said first impurity diffusion layer is formed and a second opening that is separated from said first opening; and
said step of forming said third impurity diffusion layer is comprised of a step of forming said third impurity diffusion layer that is offset from said first selective insulating film and said first impurity diffusion layer formed below said first opening in a self-alignment fashion by conducting ion implantation of impurities through said second opening.

5. The method according to claim 4, further comprising a step of forming a region of said polysilicon film immediately below said second opening to be thinner than other regions of said polysilicon film, before said step of ion implantation of impurities through said second opening.

6. The method according to claim 5,
wherein said step of forming said first impurity diffusion layer is comprised of a step of forming said first impurity diffusion layer in said semiconductor substrate by conducting said ion implantation of impurities with said second opening covered by said first resist pattern;
said step of forming said first selective insulating film is comprised of a step of forming said first selective insulating film by conducting thermal oxidation with respect to a surface of said polysilicon film exposed through said first opening and second opening formed in said first insulating film pattern after said first resist pattern is eliminated; and
said step of forming said third impurity diffusion layer comprises the steps of:
(a) eliminating said first selective insulating film formed below said second opening; and
(b) forming said third impurity diffusion layer that is offset from said first selective insulating film and said first impurity diffusion layer formed below said first opening in a self-alignment fashion by conducting ion implantation of impurities through said second opening by using said first insulating film pattern as a mask.

7. The method according to claim 1, wherein said first insulating film pattern is comprised of a silicon nitride film.

8. The method according to claim 1, further comprising a step of selectively forming a third impurity diffusion layer in said second impurity diffusion layer by conducting ion implantation of impurities by using a resist pattern as a mask after said second impurity diffusion layer is formed.

9. The method according to claim 1, further comprising a step of selectively forming a third impurity diffusion layer in said semiconductor substrate by conducting ion implantation of impurities by using a resist pattern as a mask before said second impurity diffusion layer is formed.

10. The method according to claim 1, wherein said semiconductor substrate is comprised of a single crystal silicon substrate that has a conductivity opposite to that of said first and second impurity diffusion layers.

11. The method according to claim 1,
wherein said first impurity diffusion layer is comprised of a first pair of impurity diffusion regions that are separated from each other to be symmetrical with respect to said gate electrode;
said second impurity diffusion later is comprised of a second pair of impurity regions that are separated from each other to be symmetrical with respect to said gate electrode; and
said first selective insulating film is comprised of a first pair of insulating films that are separated from each other to be symmetrical with respect to said gate electrode.

12. The method according to claim 8, wherein said third impurity diffusion layer is comprised of a third pair of impurity diffusion regions that are separated from each other to be symmetrical with respect to said gate electrode.

13. The method according to claim 9, wherein said third impurity diffusion layer is comprised of a third pair of impurity diffusion regions that are separated from each other to be symmetrical with respect to said gate electrode.

14. The method according to claim 1,
wherein said first impurity diffusion layer is comprised of a first single impurity diffusion region;
said second impurity diffusion layer is comprised of a second single impurity diffusion region; and
said first selective insulating film is comprised of a first single insulating film.

15. A method for manufacturing a gate overlap structure, comprising the steps of:
forming a first conductive film on a gate insulating film continuously formed over a semiconductor substrate;
forming a first insulating film pattern on said first conductive film;
selectively forming a first impurity diffusion layer in said semiconductor substrate by ion implanting impurities into said semiconductor substrate by using at least said first insulating film pattern as a mask;
selectively forming a first selective insulating film overlapping with said first impurity diffusion layer in said first conductive film by using said first insulating film pattern as a mask; and
forming a gate electrode that has a gate edge self-aligned with said first impurity diffusion layer and overlaps with said first impurity diffusion layer in a self-alignment fashion, said gate edge being defined by said first selective insulating film by selectively etching said first conductive film by using at least said first selective insulating film as a mask.

16. The method according to claim 15,
wherein said first conductive film is comprised of a polysilicon film; and
said step of forming said first selective insulating film is comprised of a step of forming a silicon dioxide film by conducting thermal oxidization with respect to a surface of said polysilicon film exposed through an opening formed in said first insulating pattern.

17. The method according to claim 15, wherein said first insulating film pattern is comprised of a silicon nitride film.

18. The method according to claim 15, wherein said semiconductor substrate is comprised of a single crystal silicon substrate that has a conductivity opposite to that of said first and second impurity diffusion layers.

19. The method according to claim 15,
wherein said first impurity diffusion layer is comprised of a first pair of impurity diffusion layers that are separated from each other to be symmetrical with respect to said gate electrode;
said second impurity diffusion layer is comprised of a second pair of impurity diffusion layers that are separated from each other to be symmetrical with respect to said gate electrode; and
said first selective insulating film is comprised of a first pair of insulating films that are separated from each other to be symmetrical with respect to said gate electrode.

20. The method according to claim 15,
wherein said first impurity diffusion layer is comprised of a first single impurity diffusion region;
said second impurity diffusion later is comprised of a second single impurity diffusion region; and
said first selective insulating film is comprised of a first single insulating film.
